(19) United States
(12) Patent Application Publication
(10) Pub. No.: US 2006/0151887 A1
(43) Pub. Date: Jul. 13, 2006

(54) Interconnection structure having double diffusion barrier layer and method of fabricating the same

(75) Inventors: Jun-Hwan Oh, Incheon (KR); Ja-Eung Koo, Goyang-si (KR); Se-Jong Park, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/326,301

(22) Filed: Jan. 5, 2006

(30) Foreign Application Priority Data
Jan. 13, 2005 (KR) 2005-3400

(51) Int. Cl. H01L 23/48

(52) U.S. Cl. 257/774

(57) ABSTRACT

An interconnection structure and a method of fabricating the same are provided. The interconnection structure includes an interlayer insulating layer having a structure comprising a via hole structure or a trench-shaped line structure. A conformal metal diffusion barrier layer is disposed inside the via hole structure or the trench-shaped line structure of the interlayer insulating layer. An insulating diffusion barrier spacer is disposed to cover the metal diffusion barrier layer on the sidewalls of the via hole structure or the trench-shaped line structure of the interlayer insulating layer. In addition, a copper interconnection is disposed to fill the inside of the via hole structure or the trench-shaped line structure of the interlayer insulating layer.

### CROSS-REFERENCE TO RELATED APPLICATION

This application claims priority from Korean Patent Application No. 10-2005-0003400, filed Jan. 13, 2005, the disclosure of which is incorporated by reference herein in its entirety.

### BACKGROUND OF INVENTION

1. Technical Field

The present invention relates to a semiconductor device, and more particularly, to an interconnection structure having a double diffusion barrier layer and a method of fabricating the same.

2. Discussion of the Related Art

To meet the increase in demand for integrated semiconductor devices, technology employing multi-layered metal interconnections is now being widely used. The above multi-layered metal interconnections should be formed of a metal layer having a low resistivity and a high reliability to improve the performance of the semiconductor device. Moreover, the insulating layer disposed between the multi-layered metal interconnections should be formed of a low-k dielectric layer having a low permittivity. For instance, a copper layer is widely used for the metal layer. However, it is difficult to pattern the copper layer using a typical photolithography process. Hence, a damascene process isgenerally used instead for patterning a metal layer such as the copper layer.

The damascene process is widely used to form an electrical connection between an upper copper interconnection and a lower metal interconnection. In the above mentioned damascene process, the upper copper interconnection fills a via hole and a trench region formed inside an interlayer insulating layer. The via hole is formed to expose a predetermined region of the lower metal interconnection, and the trench is formed to have a line-shaped groove running across over the via hole. However, with the above process, the upper copper interconnection may adversely affect device characteristics because copper may diffuse into the interlayer insulating layer. Therefore, a diffusion barrier layer should also be formed between the interlayer insulating layer and the copper interconnection to prevent the above-mentioned copper diffusion.

FIGS. 1A to 1C are sectional views illustrating a conventional method of fabricating an interconnection structure having a diffusion barrier layer.

Referring to FIG. 1A, a lower insulating layer 110 is formed on a semiconductor substrate 105. In addition, a lower interconnection 112 is formed inside the lower insulating layer 110 using a typical damascene process. The lower interconnection 112 is formed of a copper layer or tungsten layer.

Moreover, in the above conventional fabrication process, an interlayer insulating layer 117 is formed on the semiconductor substrate having the lower interconnection 112. The interlayer insulating layer 117 is formed of a single low-k dielectric layer to improve the operational speed of a semiconductor device, and also to prevent an interface from forming inside the interlayer insulating layer 117. The single low-k dielectric layer is formed of a silicon oxide layer including carbon, fluorine, or hydrogen, for example, a silicon oxycarbide (SiOC) layer, a carbon doped hydrogenated silicon oxide (SiOCH) layer, or a silicon oxyfluoride (SiOF) layer. The interlayer insulating layer 117 has a porous sponge shape. It is noted, however, that the interlayer insulating layer 117 may be damaged during a subsequent process, thereby leading to the possible deterioration of the low-k characteristics of the interlayer insulating layer 117. Hence, a capping layer 120 should be formed on the interlayer insulating layer 117 to protect the characteristics of the interlayer insulating layer 117. The capping layer 120 should be formed of a tetra ethyl ortho silicate (TEOS) layer, or an undoped silicate glass (USG) layer. In addition, a mask layer is formed on the capping layer 120. The mask layer is patterned, thereby forming a mask pattern 123. The mask pattern 123 is formed of a photoresist layer or a hard mask layer.

The capping layer 120 and the interlayer insulating layer are sequentially etched, using the mask pattern 123 as an etch mask, thereby forming a via hole 125 exposing the lower interconnection 112. Then, a sacrificial layer is formed on the semiconductor substrate having the via hole 125 to bury the via hole 125. The sacrificial layer is formed to prevent profile distortion of the via hole 125 during a subsequent process. The sacrificial layer is formed of a hydro-silses-quioxane (HSQ) layer or organosiloxane including hydrogen.

The sacrificial layer, the mask pattern 123, the capping layer 120, and the interlayer insulating layer 117 are sequentially patterned, thereby forming a trench region 135 inside the interlayer insulating layer 117 to run across the via hole 125. At this point, the sacrificial layer remains inside the via hole 125. Next, the sacrificial layer is removed, to expose the lower interconnection 112 at the bottom of the via hole 125.

Referring to FIG. 1B, an upper interconnection layer 150 is formed on the semiconductor substrate having the trench region 135. The upper interconnection layer 150 is formed by sequentially stacking a metal diffusion barrier layer 140 and a copper interconnection layer 146. The metal diffusion barrier layer 140 is formed of tantalum (Ta), a tantalum nitride (TaN) layer, titanium (Ti), or a titanium nitride (TiN) layer. The copper interconnection layer 146 is composed of a copper seed layer 142 and a copper layer 145, which are sequentially stacked. The copper seed layer 142 is formed using a sputtering method. Moreover, the copper layer 145 is formed using both an electroplating method and the copper seed layer 142.

Referring to FIG. 1C, the semiconductor substrate having the upper interconnection layer 150 is planarized until the capping layer 120 is exposed. As a result, an upper interconnection 150a is formed to fill the inside of the trench region 135 and the via hole 125. In the above-mentioned planarization process, the mask pattern 123 can be concurrently removed. The upper interconnection 150a is composed of a planarized metal diffusion barrier layer 140a and a copper interconnection 146a. The copper interconnection 146a is composed of a planarized copper seed layer 142a and a planarized copper layer 145a.

The planarization process is performed using a chemical mechanical polishing (CMP) method. At this point, a slurry including water or hydrogen peroxide is used during the CMP process. However, a Galvanic corrosion reaction may occur at the interface of the copper interconnection 146a and the metal diffusion barrier layer 140a during the above CMP process. As shown in FIG. 1C depicting an enlarged view of region ‘A’, corrosion can occur at the interface of the copper interconnection 146a and the metal diffusion barrier layer 140a during the CMP process. Moreover, when comparing the copper interconnection 146a with the metal diffusion barrier layer 140a (e.g. tantalum layer), corrosion occurs more easily on the surface of the copper interconnection 146a because the electrode potential for oxidation-reduction is lower. Also, the corrosion speed is further increased by the tantalum layer. The above corrosion mechanism is initiated in the water or hydrogen peroxide of the slurry (S) by the electrolysis of the copper (Cu) into Cu²⁺+electrons (e). As a result, recessed grooves G1 are formed in the copper interconnection 146a. Due to the recessed grooves G1, the trench region 135 may have portions therein, in which the width of the copper interconnection 146a have become narrower thereby leading to an increase in the electric resistance in the narrowed interconnection regions. The above-mentioned increase in electrical resistance in the narrowed interconnect regions also leads to deteroriation of the performance of the semiconductor device.

FIG. 2 is an SEM view illustrating an interconnection structure fabricated by the fabrication method of FIGS. 1A to 1C.

Referring to FIG. 2, copper interconnections 250 are aligned in parallel with interlayer insulating layers 217 or capping layers between them. Grooves G1 are found at the interfaces of the copper interconnections 250. These grooves G1 are caused by Galvanic corrosion at the interfaces of the copper interconnections 250.

FIGS. 3A to 3C are sectional views illustrating a conventional method of fabricating a via contact plug having a diffusion barrier layer.

Referring to FIG. 3A, a lower insulating layer 310 is formed on a semiconductor substrate 305. A lower interconnection 312 is formed inside the lower insulating layer 310, using a typical damascene process. The lower interconnection 312 is formed of a copper layer or a tungsten layer. An interlayer insulating layer 317 and a mask layer are sequentially formed on the semiconductor substrate having the lower interconnection 312. The mask layer is patterned, thereby forming a mask pattern 323. The mask pattern 323 is formed of a photoresist layer or a hard mask layer. The interlayer insulating layer 317 is etched, using the mask pattern 323 as an etch mask, thereby forming a via hole 325 exposing the lower interconnection 312.

Referring to FIG. 3B, the mask pattern 323 is removed. Then, a conformal metal diffusion barrier layer 340 is formed on the semiconductor substrate having the via hole 325. The metal diffusion barrier layer 340 is formed of tantalum (Ta), a tantalum nitride (TaN) layer, titanium (Ti) or a titanium nitride (TiN) layer. A copper seed layer 342 is formed on the semiconductor substrate having the metal diffusion barrier layer 340. The copper seed layer 342 is formed using a sputtering method. A copper layer 345 is formed on the semiconductor substrate having the copper seed layer 342 to bury the via hole 325. The copper layer 345 is formed using the copper seed layer 342 as a seed layer and using an electroplating method.

Referring to FIG. 3C, the semiconductor substrate having the copper layer 345 is planarized until the interlayer insulating layer 317 is exposed. As a result of the above, a via contact plug 350 is formed to fill the inside of the via hole 325. The via contact plug 350 is composed of a planarized metal diffusion barrier layer 340a, a planarized copper seed layer 342a, and a planarized copper layer 345a.

The planarization process is performed using a CMP method. At this point, a slurry including water or hydrogen peroxide is used during the CMP process. As stated above for the previous conventional embodiment of FIGS. 1A-1C, a Galvanic corrosion reaction may occur at the interface of the copper layer 345a with the copper seed layer 342a and the metal diffusion barrier layer 340a during the CMP process. Also, when comparing the copper layer 345a to the metal diffusion barrier layer 340a (e.g. tantalum layer) corrosion may occur on the surface of the copper layer 345a more easily because the electrode potential for oxidation-reduction is lower. In addition, the corrosion speed on the surface of the copper layer 345a is further increased by the tantalum layer. Furthermore, the above corrosion mechanism is initiated in the water or hydrogen peroxide of the slurry (S) by the electrolysis of the copper (Cu) into Cu²⁺+electrons (e). As a result, via recess regions G2 are formed due to the corrosion of the copper layer 345a. Hence, the possibility of contact failure occurring with upper interconnections of the interconnect structure to be formed increases due to the via recess regions G2. Moreover, layers to be formed on upper portions of the interconnect structure have non-uniform heights due to the via recess regions G2.

Therefore, there is a need for interconnection structures and methods of forming the same, which prevent corrosion of a copper layer of the interconnection structure, which typically occurs during a CMP process to form a copper interconnection.

### SUMMARY OF THE INVENTION

In accordance with an exemplary embodiment of the present invention an interconnection structure is provided. The interconnection structure includes an interlayer insulating layer comprising a structure having one of a via hole structure or a trench-shaped line structure. A conformal metal diffusion barrier layer is disposed inside the via hole structure or the trench-shaped line structure of the interlayer insulating layer. An insulating diffusion barrier spacer is disposed to cover the metal diffusion barrier layer on sidewalls of the via hole structure or the trench-shaped line structure of the interlayer insulating layer. A copper interconnection is disposed to fill the inside of the via hole structure or the trench-shaped line structure of the interlayer insulating layer.

In accordance with another exemplary embodiment of the present invention, a method of fabricating an interconnection structure is provided. The method includes forming a lower interconnection on a semiconductor substrate. An interlayer insulating layer comprising a structure having one of a via hole structure or a trench-shaped line structure is formed on the semiconductor substrate having the lower interconnection. A metal diffusion barrier layer is formed on the semiconductor substrate having the interlayer insulating layer. A conformal insulating diffusion barrier layer is formed on the semiconductor substrate having the metal diffusion barrier layer. An etch-back is performed on the semiconductor substrate having the insulating diffusion barrier layer, thereby forming an insulating diffusion barrier spacer on sidewalls of the via hole structure or the trench-shaped line structure of the interlayer insulating layer. A copper interconnection layer is formed on the semiconductor substrate having the insulating diffusion barrier spacer to fill the inside of the via hole structure or the trench-shaped line structure of the interlayer insulating layer. The semiconductor substrate having the copper interconnection layer is planarized until an upper portion of the interlayer insulating layer is exposed, thereby forming a copper interconnection.

### BRIEF DESCRIPTION OF THE DRAWINGS

FIGS. 1A to 1C are sectional views illustrating a conventional method of fabricating an interconnection structure having a diffusion barrier layer;

FIG. 2 is an SEM view illustrating an interconnection structure fabricated by the fabrication method of FIGS. 1A to 1C; FIGS. 3A to 3C are sectional views illustrating a conventional method of fabricating a via contact plug having a diffusion barrier layer;

FIG. 4 is a process flow chart illustrating a method of fabricating an interconnection structure having a double diffusion barrier layer according to an exemplary embodiment of the present invention;

FIGS. 5A to 5I are sectional views illustrating a method of fabricating an interconnection structure having a double diffusion barrier layer according to an exemplary embodiment of the present invention;

FIG. 6 is a process flow chart illustrating a method of fabricating a via contact plug interconnection structure having a double diffusion barrier layer according to an exemplary embodiment of the present invention; and

FIGS. 7A to 7E are sectional views illustrating a method of fabricating a via contact plug interconnection structure having a double diffusion barrier layer according to an exemplary embodiment of the present invention.

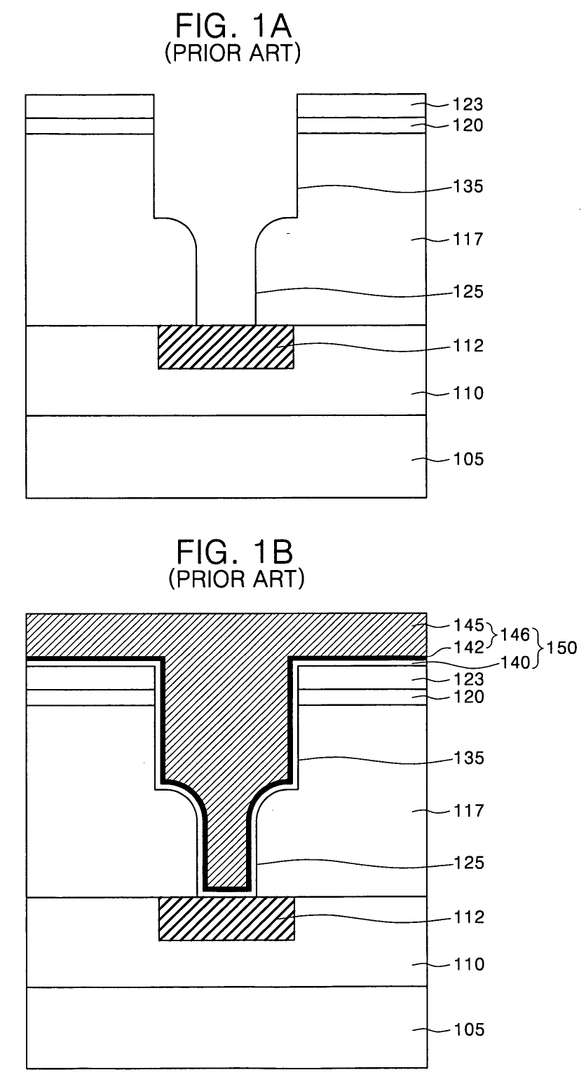

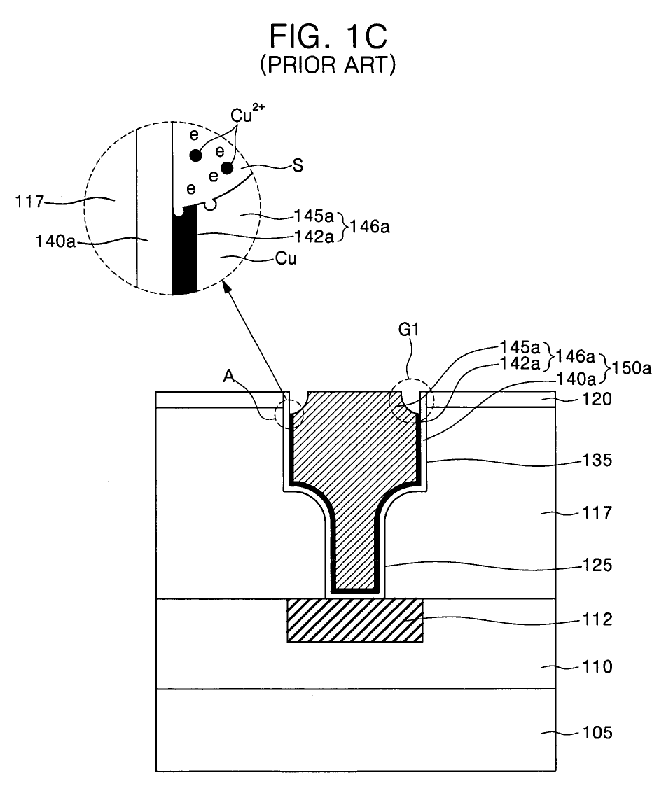

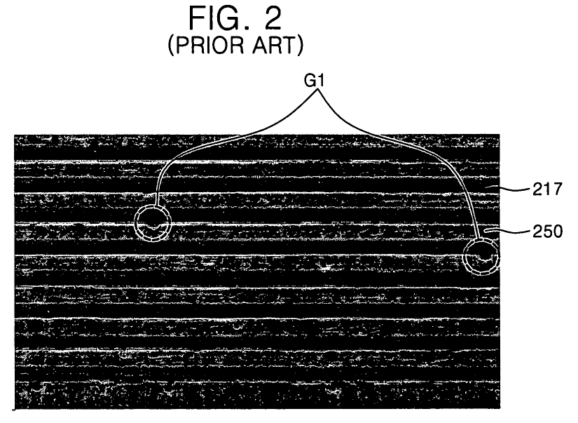

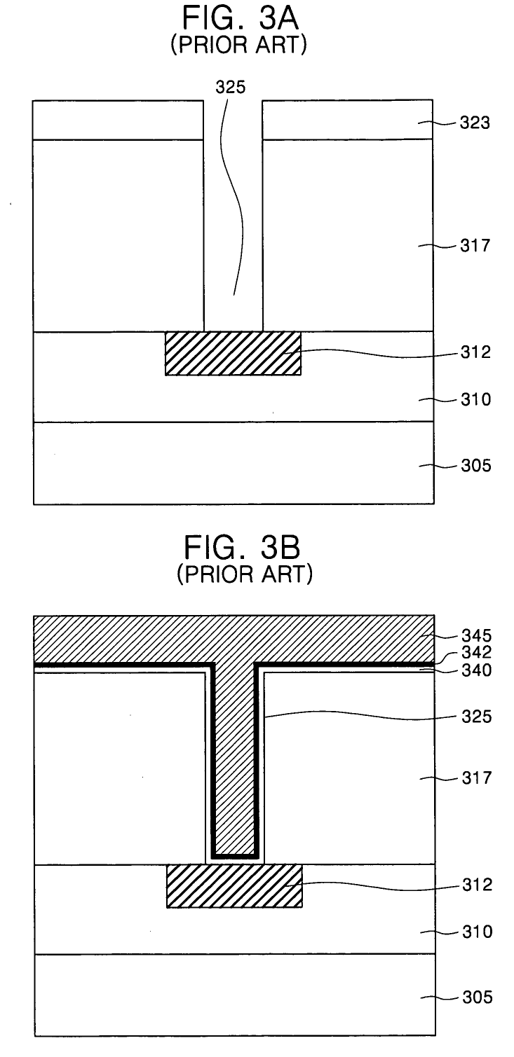

### DETAILED DESCRIPTION OF THE EXEMPLARY EMBODIMENTS OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. In the drawings, the thicknesses of layers and regions are exaggerated for clarity. Like numbers refer to like elements throughout the specification.

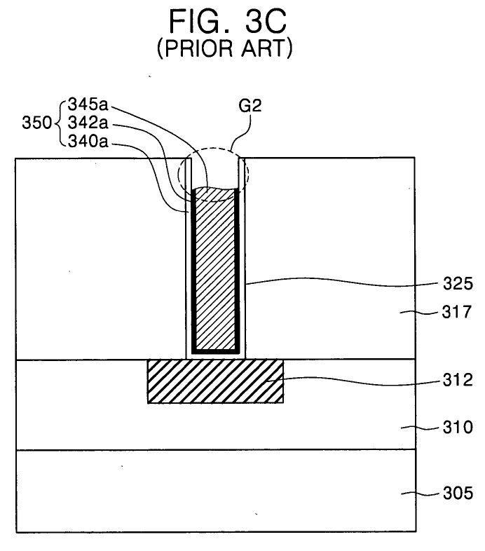

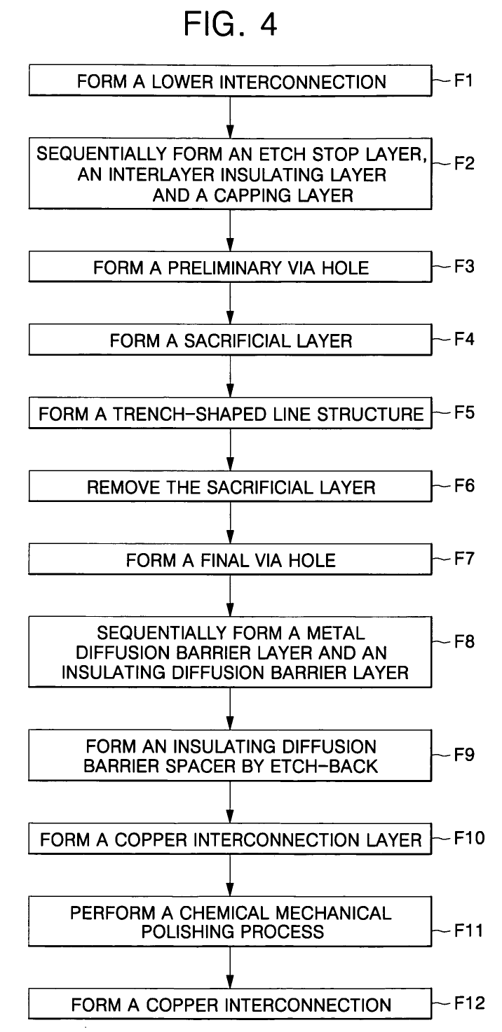

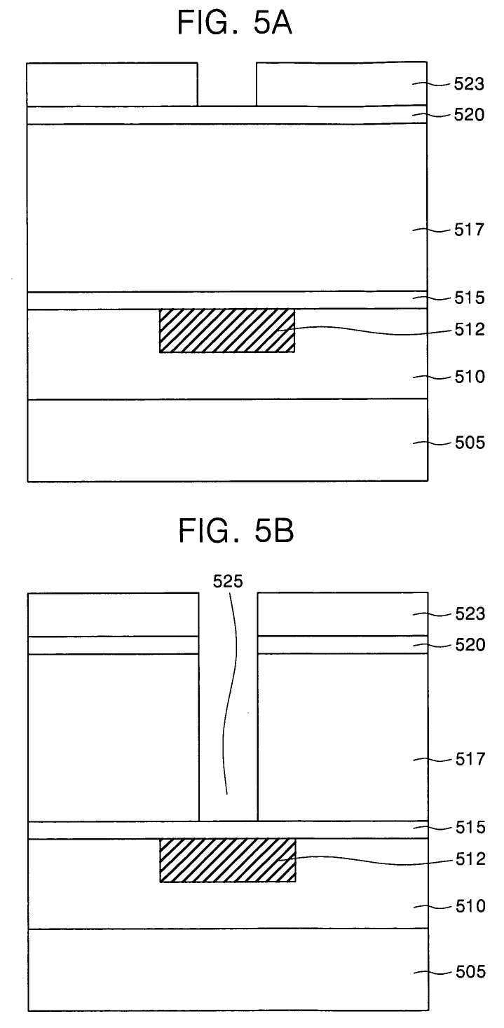

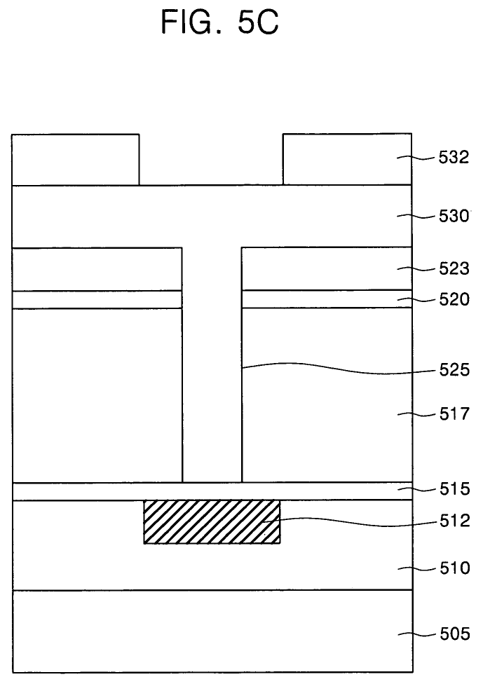

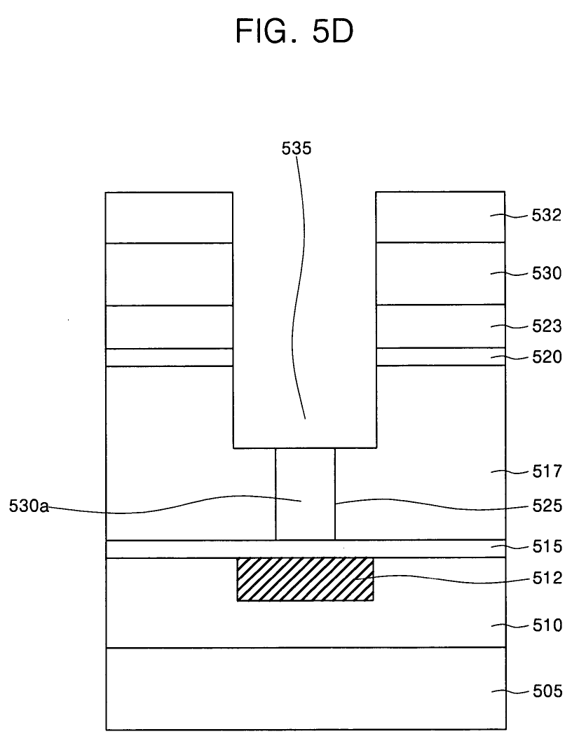

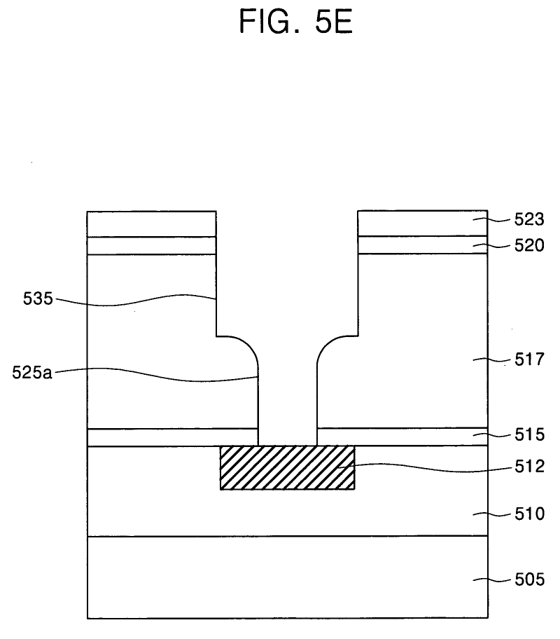

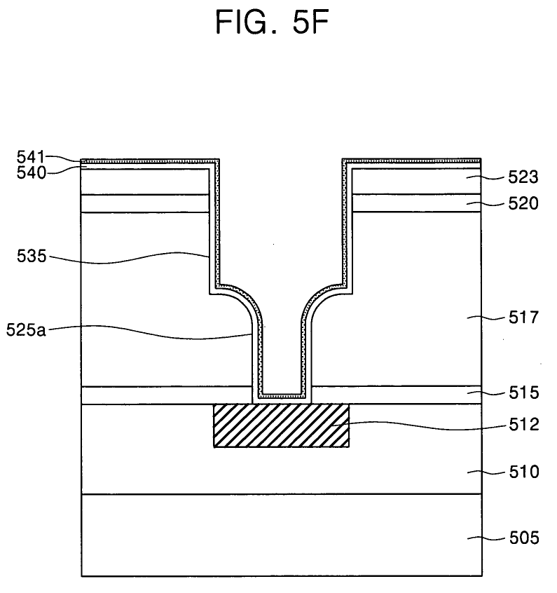

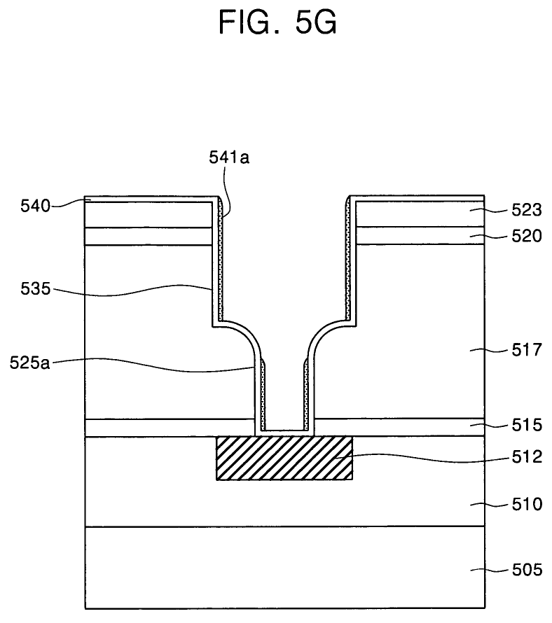

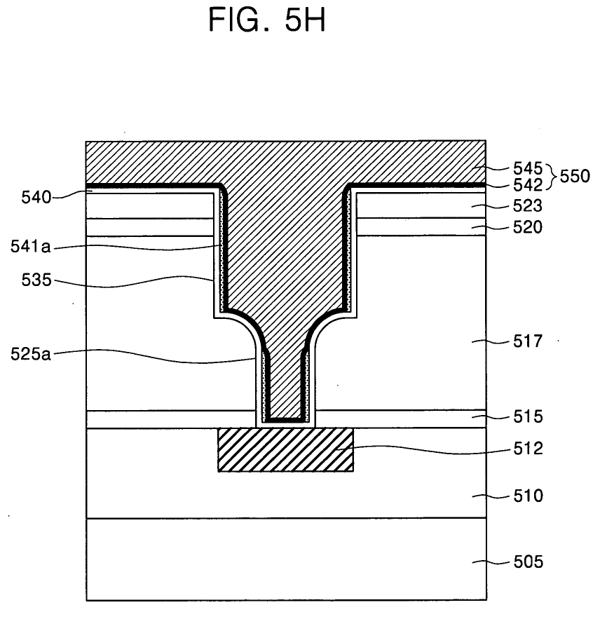

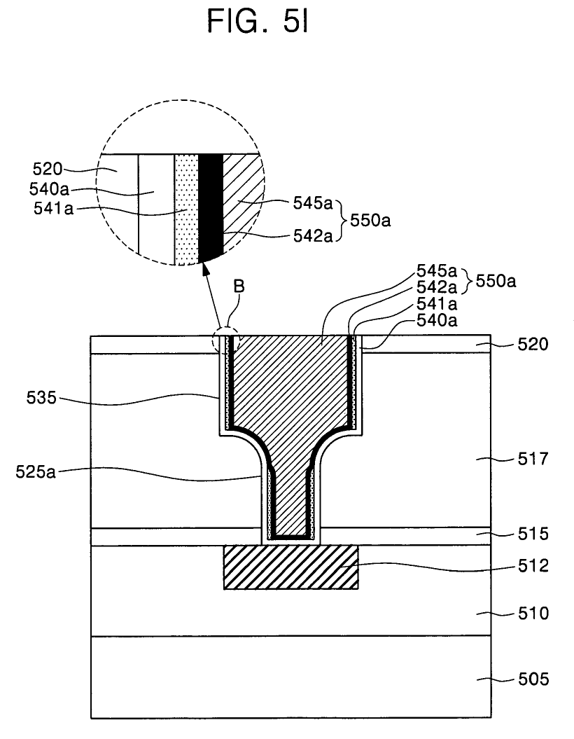

FIG. 4 is a process flow chart illustrating a method of fabricating an interconnection structure having a double diffusion barrier layer according to an exemplary embodiment of the present invention, and FIGS. 5A to 5I are sectional views illustrating a method of fabricating an interconnection structure having a double diffusion barrier layer according to an exemplary embodiment of the present invention.

Referring to FIGS. 4 and 5A, a lower insulating layer 510 is formed on a semiconductor substrate 505. A lower interconnection 512 is formed inside the lower insulating layer 510 using a typical damascene process (step F1 of FIG. 4). The lower interconnection 512 is formed of a copper layer or a tungsten layer.

An etch stop layer 515, an interlayer insulating layer 517, and a capping layer 520 are sequentially formed on the semiconductor substrate 505 (step F2 of FIG. 4). The etch stop layer 515 is preferably formed of an insulating nitride layer or an insulating carbide layer having an etch selectivity with respect to the interlayer insulating layer 517. The insulating nitride layer is formed of a silicon nitride (SiN) layer, a silicon carbon nitride (SiCN) layer, or a boron nitride (BN) layer, and the insulating carbide layer is formed of a silicon carbide (SiC) layer.

The interlayer insulating layer 517 is preferably formed of a single low-k dielectric layer to improve the operational speed of the semiconductor device, and also to prevent an interface from forming inside the interlayer insulating layer 517. The single low-k dielectric layer is formed of a silicon oxide layer including carbon, fluorine, or hydrogen, for example, a silicon oyxcarbide (SiOC) layer, a carbon doped hydrogenated silicon oxide (SiOCH) layer, or a silicon oxyflouride (SiOF) layer. The interlayer insulating layer 517 has a porous sponge shape. However, the interlayer insulating layer 517 may be damaged during a subsequent process so as to lose its property as a low-k dielectric layer. Therefore, the capping layer 520 should be formed to protect the interlayer insulating layer 517.

The capping layer 520 is preferably formed of an insulating oxide layer, an insulating nitride layer, or an insulating carbide layer. The insulating oxide layer is formed of a silicon oxide (SiO₂) layer, a tetra ethyl ortho silicate (TEOS) layer, or a low temperature oxide (LTO) layer, and the insulating nitride layer is formed of a silicon nitride (SiN) layer, a silicon carbon nitride (SiCN) layer, or a boron nitride (BN) layer. The insulating carbide layer is formed of a silicon carbide (SiC) layer.

A mask layer is formed on the capping layer 520. The mask layer is patterned, thereby forming a mask pattern 523. The mask pattern 523 is formed of a photoresist pattern or a hard mask pattern. The hard mask pattern is preferably formed of a material layer having a high etch selectivity with respect to the interlayer insulating layer 517. The hard mask pattern is formed of a SiC layer or a SiN layer.

Referring to FIGS. 4 and 5B, the capping layer 520 and the interlayer insulating layer 517 are sequentially dry-etched, using the mask pattern 523 as an etch mask. As a result of the above, a preliminary via hole 525 exposing the etch stop layer 515 on the lower interconnection 512 is formed (step F3 of FIG. 4). When the mask pattern 523 is formed of a photoresist pattern, the mask pattern 523 can be removed after the preliminary via hole 525 is formed.

Referring to FIGS. 4 and 5C, a sacrificial layer 530 is formed to bury the preliminary via hole 525 on the semiconductor substrate having the preliminary via hole 525 (step F4 of FIG. 4). A photoresist pattern 532 is formed on the sacrificial layer 530. The sacrificial layer 530 is formed to prevent profile distortion of the preliminary via hole 525 during a subsequent process. The sacrificial layer 530 is formed of a layer having a wet etch selectivity with respect to the interlayer insulating layer 517. The sacrificial layer 530 is formed of a hydro-silses-quioxane (HSQ) layer or organosiloxane.

Referring to FIGS. 4 and 5D, the sacrificial layer 530, the mask pattern 523, the capping layer 520, and the interlayer insulating layer 517 are sequentially etched, using the photoresist pattern 532 as an etch mask. As a result of the above, a trench-shaped line structure 535 is formed inside the interlayer insulating layer 517 to run across the preliminary via hole 525 (step F5 of FIG. 4). Further, a sacrificial layer 530a remains inside the preliminary via hole 525.

Referring to FIGS. 4 and 5E, the sacrificial layer 530 on the sacrificial layer 530a and the interlayer insulating layer 517 inside the preliminary via hole 525 is removed (step F6 of FIG. 4). The sacrificial layers 530 and 530a can be removed, using a wet etch solution. As a result of the above, the etch stop layer 515 at the bottom of the preliminary via hole 525 is exposed. Since the sacrificial layer 530a has a wet etch selectivity with respect to the interlayer insulating layer 517, etch damage on the surface of the interlayer insulating layer 517 is prevented.

The etch stop layer 515 exposed at the bottom of the preliminary via hole 525 is removed, thereby forming a final vial hole 525a exposing the lower interconnection 512 (step F7 of FIG. 4). The etch stop layer 515 is removed using a dry etch. While the etch stop layer 515 is etched, the mask pattern 523 is partially etched.

Referring to FIGS. 4 and 5F, a metal diffusion barrier layer 540 and a insulating diffusion barrier layer 541 are sequentially formed on the semiconductor substrate having the final via hole 325a (step F8 of FIG. 4). The metal diffusion barrier layer 540 may be formed of a single layer or a double layer. The metal diffusion barrier layer 540 is preferably formed of at least one material layer selected from the group consisting of tantalum (Ta), a tantalum nitride (TaN) layer, titanium (Ti), and a titanium nitride (TiN) layer. The insulating diffusion barrier layer 541 is formed of at least one material layer selected from the group consisting of silicon nitride (SiN), silicon carbide (SiC), silicon oxyfluoride (SiOF), and silicon oxycarbide (SiOC). The insulating diffusion barrier layer 541 is preferably formed with a thickness of about 100 angstrom (Å) to about 1000 angstroms (Å).

Referring to FIGS. 4 and 5G, the semiconductor substrate having the insulating diffusion barrier layer 541 is etched back, thereby forming insulating diffusion barrier spacers 541a on the sidewalls of the final via hole 525a and the trench-shaped line structure 535 (step F9 of FIG. 4). At this point, the etch-back is performed until the metal diffusion barrier layer 540 at the bottom of the final via hole 525a is all exposed.

Referring to FIGS. 4 and 5H, a copper seed layer 542 is formed on the semiconductor substrate having the insulating diffusion barrier spacers 541a. Then, a copper layer 545 is formed to fill the inside of the final via hole 525a and the trench-shaped line structure 535 on the semiconductor substrate having the copper seed layer 542. The copper seed layer 542 and the copper layer 545, which are sequentially stacked, constitute a copper interconnection layer 550 (step F10 of FIG. 4). The copper seed layer 542 is preferably formed using a sputtering method. The copper layer 545 is formed using both an electroplating method and the copper seed layer 542 as a seed layer.

Referring to FIGS. 4 and 5I, the semiconductor substrate having the copper interconnection layer 550 is planarized until the capping layer 520 is exposed. The planarization process uses a chemical mechanical polishing (CMP) method (step F11 of FIG. 4). As a result of the above, a copper interconnection 550a is formed inside the final via hole 525a and the trench-shaped line structure 535 (step F12 of FIG. 4). The copper interconnection 550a is composed of a planarized copper seed layer 542a and a planarized copper layer 545a. Further, concurrently, a planarized insulating diffusion barrier spacer 541a and a planarized metal diffusion barrier layer 540a are formed. At this point, the capping layer 520 is partially removed.

The CMP method preferably includes a first CMP process and a second CMP process. By way of the first CMP process, the copper interconnection layer 550 on the capping layer 520 is removed to expose the metal diffusion barrier layer 540. Then, by the second CMP process, the metal diffusion barrier layer 540 on the capping layer 520 is removed to expose an upper portion of the trench-shaped line structure 535. Further, concurrently, the metal diffusion barrier layer 540 on the trench-shaped line structure 535, the insulating diffusion barrier spacer 541a, and the copper interconnection layer 550 are partially removed. The first CMP process and the second CMP process preferably use different kinds of slurries respectively. Further, a slurry including water or hydrogen peroxide is used during the first CMP process and the second CMP process.

As described above, the insulating diffusion barrier spacer 541a is formed between the metal diffusion barrier layer 540a and the copper interconnection 550a. Thus, when the CMP process is performed using the slurry including water or hydrogen peroxide, Galvanic corrosion, which has been found in conventional fabrication processes, is prevented. In an enlarged view of a ‘B’ region depicted in FIG. 5I, it is illustrated that the insulating diffusion barrier spacer 541a electrically insulates the copper interconnection 550a and the metal diffusion barrier layer 540a.

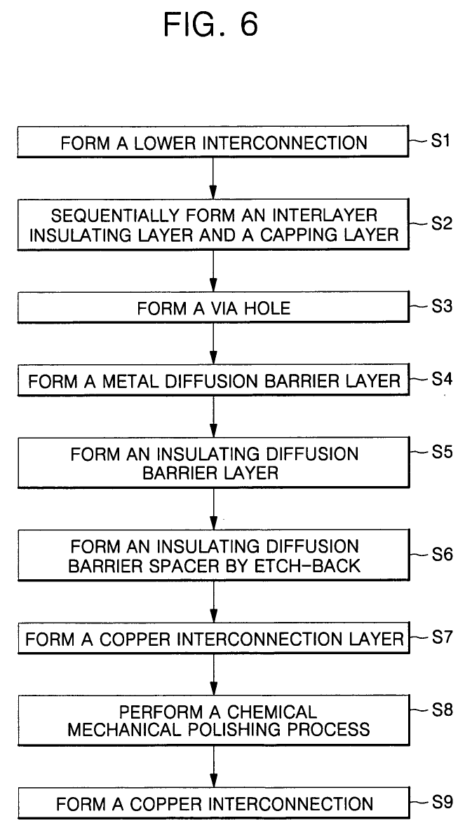

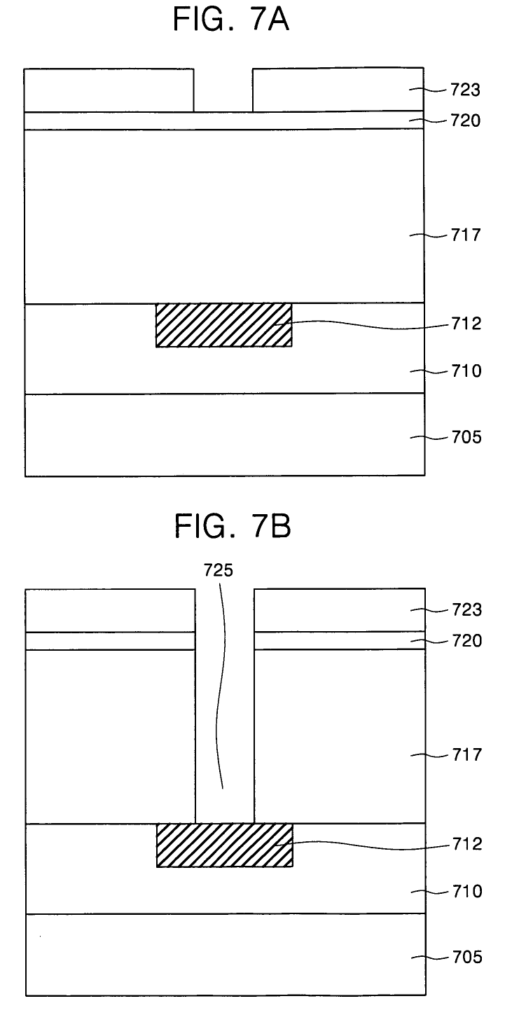

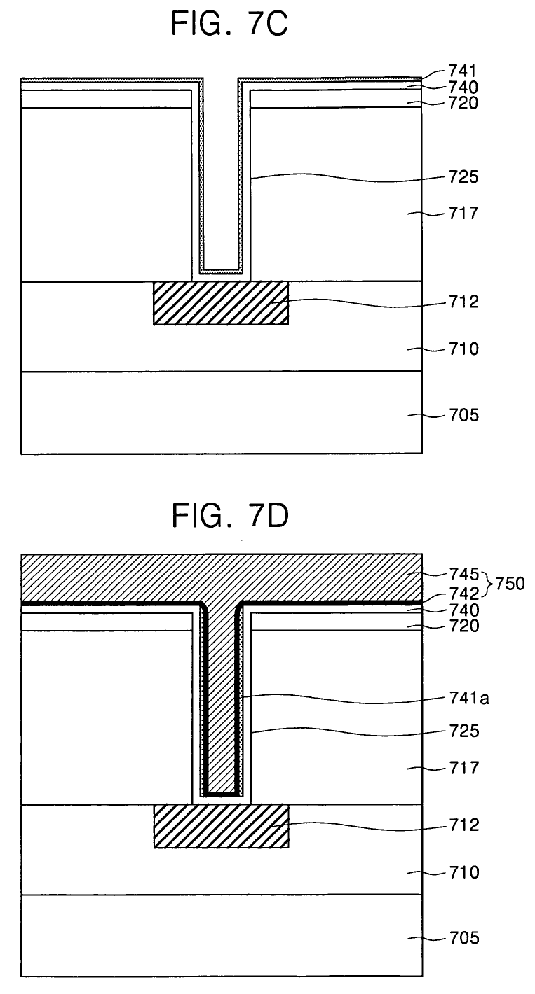

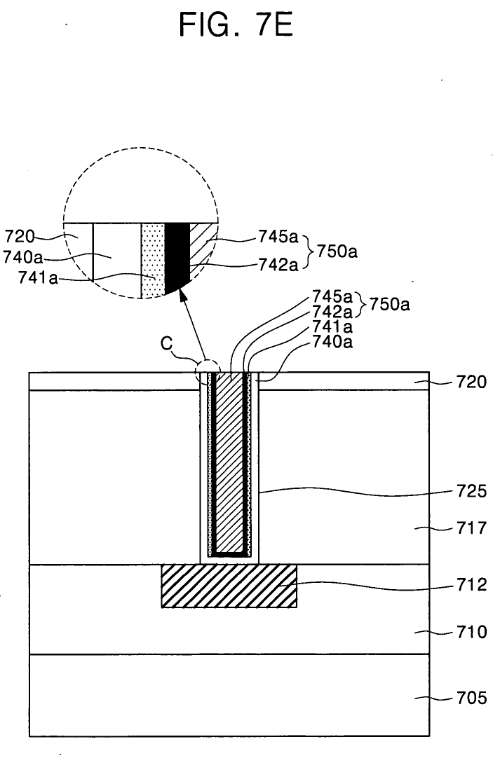

FIG. 6 is a process flow chart illustrating a method of fabricating a via contact plug interconnection structure having a double diffusion barrier layer according to an exemplary embodiment of the present invention, and FIGS. 7A to 7E are sectional views illustrating a method of fabricating a via contact plug interconnection structure having a double diffusion barrier layer according to an exemplary embodiment of the present invention.

Referring to FIGS. 6 and 7A, a lower insulating layer 710 is formed on a semiconductor substrate 705. A lower interconnection 712 is formed inside the lower insulating layer 710, using a typical damascene technique (step S1 of FIG. 6). The lower interconnection 712 is formed of a copper layer or a tungsten layer.

An interlayer insulating layer 717 is formed on a semiconductor substrate having the lower interconnection 712. A capping layer 720 is formed on the interlayer insulating layer 717 (step S2 of FIG. 6). The interlayer insulating layer 717 is formed of a silicon oxide layer or a low-k dielectric layer. The use of the low-k dielectric layer provides an effect of improving the operational speed of the semiconductor device. The low-dielectric layer is formed of a silicon oxide layer including carbon, fluorine, or hydrogen, for example, a silicon oxycarbide (SiOC) layer, a carbon doped hydrogenated silicon oxide (SiOCH) layer, or a silicon oxyfluoride (SiOF) layer. The low-dielectric layer has a porous sponge shape. As mentioned, the interlayer insulating layer 717 formed of a low-dielectric layer, may be damaged during a subsequent process so as to lose its property as a low-k dielectric layer. Thus, the capping layer 720 should be formed to protect the low-k property of the interlayer insulating layer 717.

The capping layer 720 is preferably formed of an insulating oxide layer, an insulating nitride layer, or an insulating carbide layer. The insulating oxide layer is formed of a silicon oxide (SiO₂) layer, a tetra ethyl ortho silicate (TEOS) layer, or a low temperature oxide (LTO) layer, and the insulating nitride layer is formed of a silicon nitride (SiN) layer, a silicon carbon nitride (SiCN) layer, or a boron nitride (BN) layer. The insulating carbide layer is formed of a silicon carbide (SiC) layer.

A mask layer is formed on the capping layer 720. The mask layer is patterned, thereby forming a mask pattern 723. The mask pattern 723 is formed of a photoresist pattern or a hard mask pattern. The hard mask pattern is preferably formed of a material layer having a high etch selectivity with respect to the interlayer insulating layer 717. The hard mask pattern is formed of a SiC layer or a SiN layer.

Referring to FIGS. 6 and 7B, the capping layer 720 and the interlayer insulating layer 717 are sequentially dry-etched, using the mask pattern 723 as an etch mask. As a result of the above, a via hole 725 exposing the lower interconnection 712 is formed (step S3 of FIG. 6).

Referring to FIGS. 6 and 7C, when the mask pattern 723 is formed of a photoresist pattern, after the via hole 725 is formed, the mask pattern 723 is removed. A conformal metal diffusion barrier layer 740 is formed on the semiconductor substrate having the via hole 725 (step S4 of FIG. 6). Then, an insulating diffusion barrier layer 741 is formed on the semiconductor substrate having the metal diffusion barrier layer 740 (step S5 of FIG. 6). The metal diffusion barrier layer 740 is formed of a single layer or a double layer. The metal diffusion barrier layer 740 is preferably formed of at least one material layer selected from the group consisting of tantalum (Ta), a tantalum nitride (TaN) layer, titanium (Ti), and a titanium nitride (TiN) layer. The insulating diffusion barrier layer 741 may be formed of at least one material layer selected from the group consisting of silicon nitride (SiN), silicon carbide (SiC), silicon oxyflouride (SiOF), and and silicon oxycarbide (SiOC). The insulating diffusion barrier layer 741 is preferably formed with a thickness of about 100 angstroms (Å) to about 1000 angstroms (Å).

Referring to FIGS. 6 and 7D, the semiconductor substrate having the insulating diffusion barrier layer 741 is etched back, thereby forming insulating diffusion barrier spacers 741a on the sidewalls of the final via hole 725a (step S6 of FIG. 6). At this point, the etch-back is performed until the metal diffusion barrier layer 740 at the bottom of the via hole 725 is all exposed.

A copper seed layer 742 is formed on the semiconductor substrate having the insulating diffusion barrier spacers 741a. Then, a copper layer 745 is formed to fill the inside of the via hole 725 on the semiconductor substrate having the copper seed layer 742. The copper seed layer 742 and the copper layer 745, which are sequentially stacked, constitute a copper interconnection layer 750 (step S7 of FIG. 6). The copper seed layer 742 is preferably formed using a sputtering method. The copper layer 745 is formed using an electroplating method and using the copper seed layer 742 as a seed layer.

Referring to FIGS. 6 and 7E, the semiconductor substrate having the copper interconnection layer 750 is planarized until the capping layer 720 is exposed. The planarization process may use a CMP method (step S8 of FIG. 6). As a result of the above, a copper interconnection 750a of a via contact plug structure is formed to fill the inside of the via hole 725 (step S9 of FIG. 6). The copper interconnection 750a is composed of a planarized copper seed layer 742a and a planarized copper layer 745a. Further, concurrently, a planarized insulating diffusion barrier spacer 741a and a planarized metal diffusion barrier layer 740a are formed. At this point, the capping layer 720 is partially removed.

The CMP method preferably includes a first CMP process and a second CMP process. By the first CMP process, the copper interconnection layer 750 on the capping layer 720 is removed to expose the metal diffusion barrier layer 740. Then, by the second CMP process, the metal diffusion barrier layer 740 on the capping layer 720 is removed to expose an upper portion of the capping layer 720. Further, concurrently, the metal diffusion barrier layer 740 on the via hole 725, the insulating diffusion barrier spacer 741a, and the copper interconnection layer 750 are partially removed. The first CMP process and the second CMP process preferably use different kinds of slurries respectively. Further, a slurry including water or hydrogen peroxide is used during the first CMP process and the second CMP process.

As described above, the insulating diffusion barrier spacer 741a is formed between the metal diffusion barrier layer 740a and the copper interconnection 750a. Thus, when the CMP process is performed using the slurry including water or hydrogen peroxide, the via recesses typically caused by Galvanic corrosion, encountered during conventional processes for the fabrication of a copper interconnection of a contact plug structure, are prevented from being formed. In an enlarged view of a ‘C’ region depicted in 7E, it is illustrated that the insulating diffusion barrier spacer 741a electrically insulates the copper interconnection 750a and the metal diffusion barrier layer 740a.

Interconnection structures having a double diffusion barrier layer according to other exemplary embodiments of the present invention will be explained in reference to FIGS. 5I and 7E.

FIG. 5I is a sectional view illustrating an interconnection structure having a double diffusion barrier layer according to an exemplary embodiment of the present invention.

Referring to FIG. 5I, in the interconnection structure, a lower insulating layer 510 is disposed on a semiconductor substrate 505. A lower interconnection 512 is disposed inside the lower insulating layer 510. The lower interconnection 512 is a copper layer or a tungsten layer. An etch stop layer 515 is disposed on the lower interconnection 512. An interlayer insulating layer 517 is disposed on the etch stop layer 515. A capping layer 520 is disposed on the interlayer insulating layer 517.

The interlayer insulating layer 517 is at least one material layer selected from the group consisting of a silicon oxide layer, silicon oxycarbide (SiOC), carbon doped hydrogenated silicon oxide (SiOCH), and silicon oxyflouride (SiOF). The etch stop layer 515 is preferably an insulating nitride layer or an insulating carbide layer. The insulating nitride layer is a silicon nitride (SiN) layer, a silicon carbon nitride (SiCN) layer, or a boron nitride (BN) layer, and the insulating carbide layer is a silicon carbide (SiC) layer. The capping layer 520 is an insulating oxide layer, an insulating nitride layer, or an insulating carbide layer. The insulating oxide layer is a silicon oxide (SiO₂) layer, a tetra ethyl ortho silicate (TEOS) layer, or a low temperature oxide (LTO) layer, and the insulating nitride layer is a silicon nitride (SiN) layer, a silicon carbon nitride (SiCN) layer, or a boron nitride (BN) layer. The insulating carbide layer is a silicon carbide (SiC) layer.

A trench-shaped line structure 535 is disposed inside the interlayer insulating layer 517 while penetrating the capping layer 520. A final via hole 525a is disposed to penetrate the interlayer insulating layer 517 and the etch stop layer 515 below the trench-shaped line structure 535, so as to expose the lower interconnection 512. A conformal metal diffusion barrier layer 540a is disposed inside the final via hole 525a and the trench-shaped line structure 535. An insulating diffusion barrier spacer 541a is disposed on the sidewalls of the final via hole 525a and the trench-shaped line structure 535 to cover the metal diffusion barrier layer 540a. A copper interconnection 550a is disposed to fill the inside of the final via hole 525a and the inside of the trench-shaped line structure 535. The copper interconnection 550a is composed of a copper seed layer 542a and a copper layer 545a, which are sequentially stacked.

The metal diffusion barrier layer 540a is preferably a single layer or a double layer. The metal diffusion barrier layer 540a is at least one material layer selected from the group consisting of Ta, TaN, Ti, and TiN. The insulating diffusion barrier spacer 541a is preferably at least one material layer selected from the group consisting of SiN, SiC, SiOF, and SiOC. The insulating diffusion barrier spacer 541a preferably has a thickness of about 100 Å to about 1000 Å.

As described above, the insulating diffusion barrier spacer 541a is formed between the metal diffusion barrier layer 540a and the copper interconnection 550a. In an enlarged view of a ‘B’ region depicted in FIG. 5I, it is illustrated that the insulating diffusion barrier spacer 541a electrically insulates the copper interconnection 550a and the metal diffusion barrier layer 540a.

FIG. 7E is a sectional view illustrating a via contact plug interconnection structure having a double diffusion barrier layer according to an exemplary embodiment of the present invention.

Referring to FIG. 7E, in the interconnection structure, a lower insulating layer 710 is disposed on a semiconductor substrate 705. A lower interconnection 712 is disposed inside the lower insulating layer 710. The lower interconnection 712 is a copper layer or a tungsten layer. An interlayer insulating layer 717 is disposed on the lower interconnection 712. A capping layer 720 is disposed on the interlayer insulating layer 717. The interlayer insulating layer 717 is at least one material layer selected from the group consisting of a silicon oxide layer, SiOC, SiOCH, and SiOF. The capping layer 720 is an insulating oxide layer, an insulating nitride layer, or an insulating carbide layer. The insulating oxide layer is a silicon oxide (SiO₂) layer, a tetra ethyl ortho silicate (TEOS) layer, or a low temperature oxide (LTO) layer, and the insulating nitride layer is a silicon nitride (SiN) layer, a silicon carbon nitride (SiCN) layer, or a boron nitride (BN) layer. The insulating carbide layer is a silicon carbide (SiC) layer.

A via hole 725 is disposed to penetrate the capping layer 720 and the interlayer insulating layer 717, so as to expose the lower interconnection 712. A metal diffusion barrier layer 740a is disposed inside the via hole 725. An insulating diffusion barrier spacer 741a is disposed on the sidewalls of the via hole 725 to cover the metal diffusion barrier layer 740a. A copper interconnection 750a of a via contact plug structure is disposed to fill the inside of the via hole 725. The copper interconnection 750a is composed of a copper seed layer 742a and a copper layer 745a, which are sequentially stacked.

The metal diffusion barrier layer 740a is preferably a single layer or a double layer. The metal diffusion barrier layer 740a is at least one material layer selected from the group consisting of Ta, TaN, Ti, and TiN. The insulating diffusion barrier spacer 741a is preferably at least one material layer selected from the group consisting of SiN, SiC, SiOF, and SiOC. The insulating diffusion barrier spacer 741a preferably has a thickness of about 100 Å to about 1000 Å.

As described above, the insulating diffusion barrier spacer 741a is formed between the metal diffusion barrier layer 740a and the copper interconnection 750a. In an enlarged view of a ‘C’ region of FIG. 7E, it is illustrated that the insulating diffusion barrier spacer 741a electrically insulates the copper interconnection 750a and the metal diffusion barrier layer 740a.

As described above, according to the exemplary embodiments of the present invention, an insulating diffusion barrier spacer is formed between a metal diffusion barrier layer and a copper interconnection when an interconnection structure is formed using a damascene process, thereby electrically insulating the metal diffusion barrier layer and the copper interconnection. Hence, when a CMP process is performed using a slurry including water or hydrogen peroxide, Galvanic corrosion, which typically occurs in conventional fabrication processes for a copper interconnection, is prevented by the processes and interconnect structures of the exemplary embodiments of the invention. Consequently, the accompanying recess groove difficulty, mentioned above, formed in connection with the interconnect structures manufactured by conventional fabrication processes is thereby also prevented when using the processes of the exemplary embodiments of the present invention. Thus, the processes and interconnect structures of the exemplary embodiments of the invention, minimize the malfunctioning of highly-integrated semiconductor devices malfunctions which are typically caused by the structural failure of interconnections therein.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. An interconnection structure comprising:
an interlayer insulating layer having a structure comprising one of a via hole structure or a trench-shaped line structure;
a metal diffusion barrier layer disposed inside the via hole structure or the trench-shaped line structure;
an insulating diffusion barrier spacer covering the metal diffusion barrier layer on sidewalls of the via hole structure or the trench-shaped line structure; and
a copper interconnection filling the inside of the via hole structure or the trench-shaped line structure.

2. The interconnection structure according to claim 1, wherein the metal diffusion barrier layer is a single layer or a double layer.

3. The interconnection structure according to claim 1, wherein the metal diffusion barrier layer is at least one material layer selected from the group consisting of tantalum (Ta), tantalum nitride (TaN), titanium (Ti), and titanium nitride (TiN).

4. The interconnection structure according to claim 1, wherein the insulating diffusion barrier spacer is at least one material layer selected from the group consisting of silicon nitride (SiN), silicon carbide (SiC), silicon oxyflouride (SiOF), and silicon oxycarbide (SiOC).

5. The interconnection structure according to claim 1, wherein the insulating diffusion barrier spacer has a thickness of about 100 angstroms (Å) to about 1000 angstroms (Å).

6. The interconnection structure according to claim 1, wherein the interlayer insulating layer is a material layer selected from the group consisting of silicon oxycarbide (SiOC), carbon doped hydrogenated silicon oxide (SiOCH), and silicon oxyflouride (SiOF).

7. The interconnection structure according to claim 1, wherein the copper interconnection is comprised of a copper seed layer and a copper layer, which are sequentially stacked.

8. A method of fabricating an interconnection structure comprising:
forming a lower interconnection on a semiconductor substrate
forming an interlayer insulating layer having a structure comprising one of a via hole structure or a trench-shaped line structure on the semiconductor substrate having the lower interconnection;
forming a metal diffusion barrier layer on the semiconductor substrate having the interlayer insulating layer;
forming an insulating diffusion barrier layer on the semiconductor substrate having the metal diffusion barrier layer;
performing an etch-back on the semiconductor substrate having the insulating diffusion barrier layer, thereby forming an insulating diffusion barrier spacer on sidewalls of the via hole structure or the trench-shaped line structure;
forming a copper interconnection layer to fill the inside of the via hole structure or the trench-shaped line structure on the semiconductor substrate having the insulating diffusion barrier spacer; and
planarizing the semiconductor substrate having the copper interconnection layer until an upper portion of the interlayer insulating layer is exposed, thereby forming a copper interconnection.

9. The method according to claim 8, wherein the step of forming the interlayer insulating layer having a via hole structure on the semiconductor substrate having the lower interconnection comprises:
forming the interlayer insulating layer on the semiconductor substrate having the lower interconnection;
forming a mask layer on the interlayer insulating layer;
patterning the mask layer, thereby forming a mask pattern; and
etching the interlayer insulating layer, using the mask pattern as an etch mask, thereby forming the via hole structure exposing the lower interconnection.

10. The method according to claim 9, wherein the step of forming an interlayer insulating layer having a trench-shaped line structure on the semiconductor substrate having the lower interconnection comprises:
forming a sacrificial layer to bury the via hole on the semiconductor substrate having the via hole;
forming a photoresist pattern on the sacrificial layer;
dry-etching the sacrificial layer, the mask pattern, and the interlayer insulating layer sequentially, using the photoresist pattern as an etch mask, thereby forming the trench-shaped line structure inside the interlayer insulating layer to run across the via hole; and
sequentially removing the photoresist pattern and the sacrificial layer so as to expose the lower interconnection.

11. The method according to claim 8, wherein the metal diffusion barrier layer is formed of a single layer or a double layer.

12. The method according to claim 8, wherein the metal diffusion barrier layer is formed of at least one material layer selected from the group consisting of tantalum (Ta), tantalum nitride (TaN), titanium (Ti), and titanium nitride (TiN).

13. The method according to claim 8, wherein the step of performing an etch-back on the semiconductor substrate having the insulating diffusion barrier layer is performed until the metal diffusion barrier layer is exposed at a bottom of the via hole structure or the trench-shaped line structure of the interlayer insulating layer.

14. The method according to claim 8, wherein the insulating diffusion barrier layer is formed of at least one material layer selected from the group consisting of silicon nitride (SiN), silicon carbide (SiC), silicon oxyflouride (SiOF), and silicon oxycarbide (SiOC).

15. The method according to claim 8, wherein the insulating diffusion barrier layer is formed with a thickness of about 100 angstroms (Å) to about 1000 angstroms (Å).

16. The method according to claim 8, wherein the interlayer insulating layer is formed of at least one material layer selected from the group consisting of silicon oxycarbide (SiOC), carbon doped hydrogenated silicon oxide (SiOCH), and silicon oxyflouride (SiOF).

17. The method according to claim 8, wherein the copper interconnection is composed of a copper seed layer and a copper layer, which are sequentially stacked.

18. The method according to claim 17, wherein the step of forming the copper interconnection comprises:
forming the conformal copper seed layer on the semiconductor substrate having the insulating diffusion barrier spacer;
forming the copper layer to fill the inside of the via hole structure or the trench-shaped line structure of the interlayer insulating layer on the semiconductor substrate having the copper seed layer; and
planarizing the semiconductor substrate having the copper layer until an upper portion of the interlayer insulating layer is exposed.

19. The method according to claim 18, wherein the copper seed layer is formed using a sputtering method.

20. The method according to claim 18, wherein the copper layer is formed using an electroplating method.

21. The method according to claim 8, wherein the planarization process uses a chemical mechanical polishing (CMP) method.

22. The method according to claim 21, wherein the planarization process includes a first CMP process and a second CMP process.

23. The method according to claim 22, wherein the first CMP process is performed to remove the copper interconnection layer on the interlayer insulating layer, so as to expose the metal diffusion barrier layer,
the second CMP process is performed to remove the metal diffusion barrier layer on the interlayer insulating layer, so as to expose an upper portion of the interlayer insulating layer, and concurrently,
the metal diffusion barrier layer, the insulating diffusion barrier spacer, and the copper interconnection layer on the via hole structure or the trench-shaped line structure of the interlayer insulating layer are partially removed.

24. The method according to claim 23, wherein the first CMP process and the second CMP process use different kinds of slurries respectively.

25. The method according to claim 24, wherein the first CMP process and the second CMP process use slurries comprising one of water or hydrogen peroxide.
